(19) United States
(12) Patent Application Publication
(10) Pub. No.: US 2003/0072879 A1
(43) Pub. Date: Apr. 17, 2003

(54) Method of providing protection by aluminizing metal parts constituted at least partially by a honeycomb structure

(75) Inventors: Jean-Paul Fournes, Dannemois (FR); Jacques Leger, Combs-La-Ville (FR); Catherine Richin, Roinville-Sous-Dourdan (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: SNECMA MOTEURS, PARIS (FR)

(21) Appl. No.: 10/268,750

(22) Filed: Oct. 11, 2002

(30) Foreign Application Priority Data
Oct. 16, 2001 (FR) 01 13313

(51) Int. Cl. C23C 16/00

(52) U.S. Cl. 427/250

(57) ABSTRACT

At least one gaseous precursor of the deposit to be made and comprising an aluminum compound is brought with the help of a carrier gas into contact with the surfaces of parts placed in an enclosure. The carrier gas is selected from helium and argon, and the pressure inside the enclosure is selected in such a manner that the mean free path of the carrier gas molecules is at lest twice as long as that of argon molecules under atmospheric pressure. The method is particularly suitable for aluminizing a low pressure turbine ring sector of a turbomachine, the sector being provided with an abradable honeycomb coating.

### BACKGROUND OF THE INVENTION

The invention relates to providing protection against oxidation at high temperature to metal parts constituted at least partially by a honeycomb structure.

The field of the invention is more particularly that of protecting abradable honeycomb coatings formed on low pressure turbine parts in turbomachines. The field of application nevertheless extends to any aviation component of honeycomb structure that needs to be protected against corrosion by oxidation at high temperature.

In a low pressure turbine of a turbomachine, air seals are formed between the tips of the rotor blades and a ring of the turbine stator which surrounds them, and also between the free ends of the stator blades and a ring of the turbine rotor which faces them, for the purpose of opposing the direct passage of air through the gaps between the tips of the rotor or stator blades and the facing annular portions on the stator or rotor. It is known to provide the rotor portions with an abradable coating which can be made of a metal honeycomb structure secured by brazing and having the axes of the cells extending substantially radially. The moving parts can penetrate over a fraction of the height of the cells by means of the edges of the tips of the moving blades or of projecting portions carried by the rotor and referred to as wipers.

Although made of metal alloys having good behavior at high temperature, such honeycomb structures are subject to deterioration by oxidation. The stagnation of very hot combustion gas in the cells produces corrosion that can lead to localized destruction of the honeycomb coating. This results in leaks occurring at the periphery of the turbine ring or the rotor, with hot points forming and with the efficiency of the turbine decreasing significantly. Replacing the abradable honeycomb coating requires the turbine to be taken out of service and that represents a cost that is very high when it needs to be performed frequently.

A method of protection that is commonly used is aluminization by vapor deposition. That method is well known; in particular reference can be made to French patent document No. 1 433 497. It consists in placing one or more parts that are to be protected in an enclosure having flowing therein a gaseous mixture that contains an aluminum compound, such as a halide, together with a dilution gas or carrier gas. The halide is produced by reacting a halogen, e.g. chlorine or fluorine with a metal donor containing aluminum, for example a metal alloy of aluminum with one or more metal components of the material from which the parts to be protected are made. The dilution gas serves to dilute and entrain the gaseous mixture so as to bring the halide into contact with the parts in order to form the desired deposit on the surfaces thereof. The dilution gas that is commonly used is argon. Hydrogen is also mentioned in above-specified document FR 1 433 497, but it is very difficult to use in practice of the danger it represents.

For stationary parts of a low pressure turbine, aluminization must be performed after the abradable honeycomb coating has been brazed onto the parts since it is not possible to perform brazing after aluminization.

The conventional method of aluminization by vapor deposition does indeed enable a satisfactory protective layer to be formed on the outside surfaces of the parts, but it does not form such a protective layer all the way to the closed ends of the cells. Unfortunately, protection against high temperature oxidation is required not only in the vicinity of the openings of the cells, but also all the way to the ends thereof where hot combustion gases can stagnate.

### OBJECT AND SUMMARY OF THE INVENTION

An object of the invention is to propose a method enabling all of the exposed surfaces of parts made at least in part out of a honeycomb structure to be protected by aluminization, and in particular to enable all the faces of the cells of said structure to be protected.

This object is achieved by a method in which at least one gaseous precursor of the deposit to be made and comprising an aluminum compound is brought together with a carrier gas into contact with the surfaces of the part placed in an enclosure, in which method, according to the invention, the carrier gas is selected from helium and argon, and the pressure inside the enclosure is selected in such a manner that the mean free path of carrier gas molecules is at least twice as long as that of argon molecules under atmospheric pressure.

Lengthening the mean free path of the carrier gas molecules facilitates penetration into the cells of the honeycomb structure and thus enables precursor gas molecules to be brought into contact with the inside faces of the cells, all the way to the ends thereof. As a result, the entire surface of the part is aluminized and thus protected, thus considerably prolonging its lifetime.

In an implementation of the invention, helium is used as the carrier gas and the method can be implemented at atmospheric pressure, or at a pressure below atmospheric pressure.

In another implementation of the invention, argon is used as the carrier gas and the method is advantageously implemented at a pressure of not greater than 50 kilopascals (kPa) and preferably not greater than 25 kPa.

### BRIEF DESCRIPTION OF THE DRAWINGS

The invention will be better understood on reading the following description given by way of non-limiting indication and with reference to the accompanying drawing, in which:

FIG. 1 is a highly diagrammatic meridian section of a portion of a low pressure turbine in a turbomachine;

FIG. 2 is a fragmentary perspective view of a sector of the ring in FIG. 1; and

FIG. 3 is a highly diagrammatic view of an installation enabling the method of the invention to be performed.

### DETAILED DESCRIPTION OF IMPLEMENTATIONS

Implementations of the invention are described below in an application of the method to forming a protective layer on ring sectors carried by the stationary blades in a low pressure turbine of a turbomachine. It will immediately be seen that the method is appropriate for sectors of a stationary ring in a low pressure turbine fitted with an abradable honeycomb structure, and indeed to any metal part, in particular any aviation component, formed at least partially by a honeycomb structure.

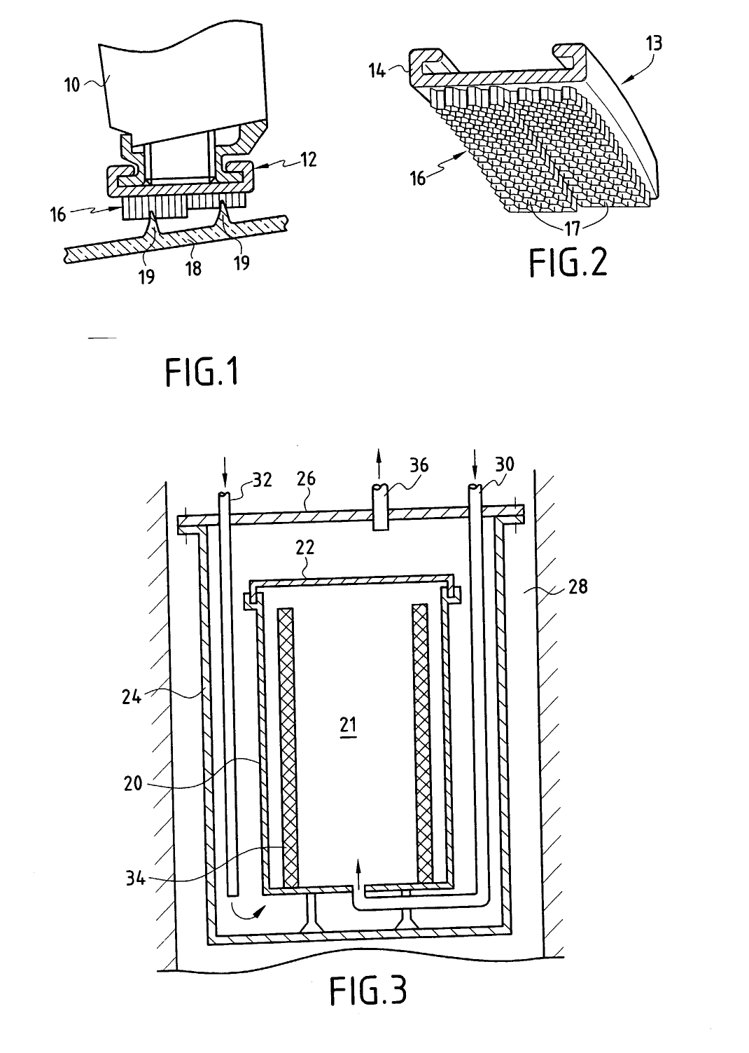

In a low pressure turbine as shown very diagrammatically in section in FIG. 1, the stator air-guiding blades 10 have their free ends engaged with a ring 12 made up of juxtaposed sectors. Each ring sector 13 (FIG. 2) comprises a shroud sector 14 carrying, on the inside, a honeycomb structure 16.

The shroud sector 14 is made of a metal material, e.g. a superalloy based on nickel or cobalt such as “HA214” (NC16Fe) or “Hastelloy X” (NC22FeD) or “HA188” (KCN22W). The honeycomb structure 16 is also made of a metal material, e.g. a superalloy based on cobalt or based on iron such as “HA214”, and it is brazed onto the shroud sector 14 or directly onto the turbine nozzle.

In section (FIG. 1), the structure 16 is of stepped profile corresponding approximately to the profile of the annular portion of the rotor 18 of the turbomachine facing it. The rotor 18 has projecting portions 19 or “baffle wipers” which, in operation of the turbomachine, penetrate into the honeycomb structure 16 forming an abradable coating on the ring 12.

The cells 17 of the honeycomb structure 16 have their axes extending substantially radially. By way of indication, the cells 17 may be 5 millimeters (mm) to 20 mm high and the wipers 19 may penetrate into the honeycomb structure by about 2 mm to 3 mm.

In combination, the configuration of the wipers 19 and of the abradable structure 16 serves to constitute a peripheral seal opposing direct passage of combustion gases through the gap between the rotor 18 and the ring 12. The high temperature of the gas, which may exceed 1000° C., makes it necessary to provide protection against high temperature oxidation on the exposed surfaces of the ring sectors, including on the inside walls of the cells 17.

Such protection is formed by a method of the invention, e.g. by using the installation shown in FIG. 3 for vapor aluminization.

This installation comprises a vessel 20 closed by a cover 22 in non-leaktight manner and supported inside a pot 24. The pot is closed in leaktight manner by a cover 26 and is placed inside an oven 28.

A pipe 30 feeds the enclosure 21 defined by the vessel 20 with a carrier gas (or dilution gas). The same gas is injected into the pot 24 outside the vessel 20 via a pipe 32. This sweeping gas is recovered through the cover 26 by means of a pipe 36.

Inside the vessel 20 there is disposed a donor 34, e.g. in the form of granules or a powder. The donor is generally constituted by an alloy of aluminum and one or more of the metals constituting the parts to be aluminized. An activator enabling a halide to be formed with the donor is also put into the enclosure in the form of a powder. Commonly used activators are ammonium fluoride NH₄F or aluminum fluoride AlF₃.

Ring sectors 13 for aluminizing, after the honeycomb structures 16 have been brazed onto the shroud sectors 14, are placed inside the enclosure 21, being supported by or suspended from tooling (not shown). Additional donor blocks may be placed facing the openings in the cells, and at a distance therefrom.

The temperature of the oven is controlled so as to enable a gaseous halide to form by reaction between the donor and the activator, this temperature generally lies in the range 950° C. to 1200° C. Aluminization is performed by deposition when the halide decomposes on coming into contact with the surfaces to be protected. The function of the carrier gas is to facilitate transport of the halide molecules.

In a first implementation of the invention, the carrier gas used is helium.

Compared with argon which is the gas that is usually used, helium molecules have a mean free path that is considerably longer, at given pressure. The mean free path length L is usually defined as being proportional to 1/P.D² where P is pressure and D is molecule diameter. The ratio L_{He}/L_{Ar} between the mean free paths of molecules of helium and of argon is approximately equal to 3 at atmospheric pressure.

By lengthening the mean free path of carrier gas molecules, the diffusion of halide within the cells 17 of the ring sectors 13 is facilitated such that aluminization takes place not only on the outside surfaces of the ring sectors, but also over the entire inside walls of the cells.

In a second implementation of the invention, the carrier gas used is argon, but the aluminization process is carried out at reduced pressure, likewise for the purpose of lengthening the mean free path length of the carrier gas molecules.

Thus, after the ring sectors have been loaded into the enclosure 21 of the installation shown in FIG. 3, and the pot 24 has been closed in leaktight manner, the atmospheric inside the pot 24 and thus also the vessel 20 is purged under argon and its pressure is reduced by pumping via the pipe 26 so as to bring the pressure inside the pot 24 and the vessel 20 to a relatively low value, e.g. below 5 kPa. Thereafter, a continuous stream of argon is admitted via the pipe 30 so as to maintain pressure inside the pot 24 and the vessel 20 at a value lower than atmospheric pressure. The value of this pressure may be selected to be not greater than 50 kPa, and preferably to be not greater than 25 kPa, the ratio L_{Ar low}/L_{Ar atm} between the mean free path length of argon molecules at low pressure and at atmospheric pressure then being at least 2 and preferably at least 4.

Tests

Turbine ring sectors similar to the sector shown in FIGS. 1 and 2 were aluminized using an installation of the type shown in FIG. 3, the donor being a chromium-aluminum alloy with 30%-35% aluminum, and the activator being AlF₃.

The process was carried out with the temperature inside the enclosure 21 being equal to about 1000° C. for a duration of about 5 hours (h).

Three tests A, B, and C were performed, respectively using argon under atmospheric pressure (the prior art method of aluminization by vapor deposition), with helium, and with argon under low pressure equal to about 13 kPa.

For each test, honeycomb structures were used that presented cells of various heights H (or depths) respectively equal to 9 mm, 11 mm, and 15 mm, and the thickness of the aluminum deposit formed on the inside walls of the cells was measured in the immediate vicinity of their openings (high), at the bottoms of the side walls of the cells (low) and on the end walls thereof (end).

The table below gives the measured thicknesses in micrometers (μm).

| | | H = 9 mm | H = 11 mm | H = 15 mm |
|---|---|---|---|---|
| A | high | 46 | 45 | 32 |
| | low | 0 | 0 | 0 |
| | end | 0 | 0 | 0 |
| B | high | 41 | 35 | 34 |
| | low | 31 | 38 | 23 |
| | end | 40 | 38 | 19 |
| C | high | 41 | 29 | 32 |
| | low | 53 | 34 | 31 |
| | end | 32 | 26 | 26 |

Whereas a coating was obtained at the tops of the cells in all cases, only methods performed in accordance with the invention were able to apply a coating over the entire inside walls of the cells all the way down to the bottoms of the side walls and over the end walls.

It should be observed that in test C (Ar at low pressure), the ratio L_{Ar low}/L_{Ar atm} was equal to about 7.8, whereas in test B (He at atmospheric pressure) the ratio L_{He}/L_{Ar atm} was equal to about 3.

The process of aluminization with a carrier gas constituted by helium could also be performed under low pressure in order to obtain a ratio L_{He low}/L_{Ar atm} greater than 3, thereby further encouraging penetration of precursor molecules into the bottoms of the cells.

What is claimed:

1/ A method of aluminization by vapor deposition for providing protection against high temperature oxidation to a metal part constituted at least partially by a honeycomb structure, in which method at least one gaseous precursor of the deposit to be made and comprising an aluminum compound is brought together with a carrier gas into contact with the surfaces of the part placed in an enclosure, wherein the carrier gas is selected from helium and argon, and the pressure inside the enclosure is selected in such a manner that the mean free path of carrier gas molecules is at least twice as long as that of argon molecules under atmospheric pressure.

2/ A method according to claim 1, the method being performed under atmospheric pressure, using helium as the carrier gas.

3/ A method according to claim 1, the method being performed at a pressure lower than atmospheric pressure, using helium as the carrier gas.

4/ A method according to claim 1, the method being performed at a pressure not greater than 50 kPa, using argon as the carrier gas.

5/ A method according to claim 1, the method being performed at a pressure not greater than 25 kPa, using argon as the carrier gas.

6/ A method according to claim 1, for aluminizing a low pressure turbine ring sector of a turbomachine, the sector being provided with an abradable honeycomb coating.
